(19) United States
(12) Patent Application Publication
(10) Pub. No.: US 2024/0213401 A1
(43) Pub. Date: Jun. 27, 2024

(54) TEXTURED LUMIPHORE LAYER TO IMPROVE LIGHT EXTRACTION FOR LIGHT-EMITTING DIODE CHIPS AND RELATED METHODS

(71) Applicant: CreeLED, Inc., Durham, NC (US)

(72) Inventors: David Suich, Durham, NC (US); Michael Check, Holly Springs, NC (US); Colin Blakely, Raleigh, NC (US); Robert Wilcox, Rolesville, NC (US); Andre Pertuit, Raleigh, NC (US)

(21) Appl. No.: 18/085,672

(22) Filed: Dec. 21, 2022

(51) Int. Cl. H01L 33/00; H01L 21/304; H01L 21/324

(52) U.S. Cl. CPC H01L 33/0095; H01L 21/304; H01L 21/3247; H01L 2933/0058

(57) ABSTRACT

The present disclosure relates to solid-state lighting devices including light-emitting diodes (LEDs) and more particularly to light-extraction features for LED chips and packages and methods of forming the light-extraction features on a cover structure over the LED chip to improve light extraction from the LED chip. A number of sublayers that are embedded with lumiphoric materials can be pressed in a mold that includes texturing that imprints the light-extraction features in the sublayers. The sublayers can then be baked to form a cover structure that can be placed over the LED chip. In other embodiments, the sublayers can be baked to form the cover structure, which can then be heated to above a transition temperature of the cover structure, then pressed in a textured mold to form the light-extraction features, and then placed over the LED chip.

### FIELD OF THE DISCLOSURE

The present disclosure relates to solid-state lighting devices including light-emitting diodes (LEDs) and more particularly to light-extraction features for LED chips and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from silicon carbide, gallium nitride, gallium phosphide, aluminum nitride, and/or gallium arsenide-based materials and/or from organic semiconductor materials. Photons generated by the active region are initiated in all directions.

Typically, it is desirable to operate LEDs at the highest light emission efficiency, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by a number of factors, including internal reflection. If photons are internally reflected in a repeated manner, then such photons will eventually be absorbed and never provide visible light that exits an LED. To increase the opportunity for photons to exit an LED, it has been found useful to pattern, roughen, or otherwise texture the interface between an LED surface and the surrounding environment to provide a varying surface that increases the probability of refraction over internal reflection and thus enhances light extraction. Reflective surfaces may also be provided to reflect generated light so that such light may contribute to useful emission from an LED chip. LEDs have been developed with internal reflective surfaces or layers to reflect generated light.

As advancements in modern LED technology progress, the art continues to seek improved LEDs and solid-state lighting devices having desirable illumination characteristics capable of overcoming challenges associated with conventional lighting devices.

### SUMMARY

The present disclosure relates to solid-state lighting devices including light-emitting diodes (LEDS) and more particularly to light-extraction features for LED chips and packages and methods of forming the light-extraction features on a cover structure over the LED chip to improve light extraction from the LED chip. Light-extraction features include structures formed in or on light-emitting surfaces of substrates. A number of sublayers that are embedded with lumiphoric materials can be pressed in a mold that includes texturing that imprints the light-extraction features in the sublayers. The sublayers can then be baked to form a cover structure that can be placed over the LED chip. In other embodiments, the sublayers can be baked to form the cover structure, which can then be heated to above a transition temperature of the cover structure, then pressed in a textured mold to form the light-extraction features, and then placed over the LED chip.

In one aspect, a method for fabricating an LED package can include laminating a plurality of sublayers, each embedded with a lumiphoric material. The method can also include pressing the plurality of sublayers into a mold, wherein the mold comprises a textured surface that results in a plurality of light extraction features formed on a surface of the plurality of sublayers. The method can also include baking or sintering the sublayers to form a cover structure with a textured surface. The method can also include fixing the cover structure to the LED package, wherein the cover structure covers an LED chip on the LED package.

In one aspect, a method for fabricating an LED package can include laminating a plurality of sublayers, each embedded with a lumiphoric material. The method can also include baking or sintering the sublayers to form a cover structure. The method can also include heating the cover structure and a plunger and a mold to a predefined temperature. The method can also include pressing cover structure into the mold with the plunger, wherein at least one of the plunger or mold comprises a textured surface that results in a plurality of light extraction features formed on a surface of the cover structure. The method can also include fixing the cover structure to the LED package, wherein the glass cover structure covers an LED chip on the LED package.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is an exemplary generalized light-emitting diode (LED) package with light-extraction features according to one or more embodiments of the disclosure.

FIGS. 1B and 1C are exemplary depictions of light rays and escape cones according to one or more embodiments of the disclosure.

FIGS. 2A-2C illustrate exemplary steps in a method to manufacture an LED package with light-extraction features according to one or more embodiments of the disclosure.

FIGS. 3A-3D illustrate exemplary steps in another method to manufacture an LED package with light-extraction features according to one or more embodiments of the disclosure.

FIGS. 4A-4D illustrate exemplary steps in method of baking or heating a cover structure after light-extraction features are formed according to one or more embodiments of the disclosure.

FIGS. 5A and 5B illustrate different orientations of a cover structure with light-extraction features according to one or more embodiments of the disclosure.

FIGS. 6A-6C illustrate different shapes of light-extraction features according to one or more embodiments of the disclosure.

FIG. 7 is a graph depicting a change in emission profile over angle according to one or more embodiments of the disclosure.

FIG. 8 is a flowchart depicting a method for fabricating an LED package according to one or more embodiments of the disclosure.

FIG. 9 is a flowchart depicting another method for fabricating an LED package according to one or more embodiments of the disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDS) and more particularly to light-extraction features for LED chips and packages and methods of forming the light-extraction features on a cover structure over the LED chip to improve light extraction from the LED chip. Light-extraction features include structures formed in or on light-emitting surfaces of substrates. A number of sublayers that are embedded with lumiphoric materials can be pressed in a mold that includes texturing that imprints the light-extraction features in the sublayers. The sublayers can then be baked to form a cover structure that can be placed over the LED chip. In other embodiments, the sublayers can be baked to form the cover structure, which can then be heated to above a transition temperature of the cover structure, then pressed in a textured mold to form the light-extraction features, and then placed over the LED chip.

An LED chip typically comprises an active LED structure or region that may have many different semiconductor layers arranged in many different ways. The fabrication and operation of LEDs and their active structures are generally known in the art and are only briefly discussed herein. The layers of the active LED structure may be fabricated using known processes with a suitable process being metal organic chemical vapor deposition. The layers of the active LED structure typically comprise many different layers and generally comprise an active layer sandwiched between n-type and p-type oppositely doped epitaxial layers, all of which are formed successively on a growth substrate. It is understood that additional layers and elements may also be included in the active LED structure, including, but not limited to, buffer layers, nucleation layers, super lattice structures, un-doped layers, cladding layers, contact layers, and current-spreading layers and light extraction layers and elements. The active layer may comprise a single quantum well, a multiple quantum well, a double heterostructure, or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

Different embodiments of the active LED structure may emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denoted with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The LED chip may also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In some embodiments, the combination of the LED chip and the one or more phosphors emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In some embodiments, one or more phosphors may include yellow phosphor (e.g., YAG:Ce), green phosphor (e.g., LuAg:Ce), and red phosphor (e.g., Ca_{i-x-y}SrₓEu_{y}AlSiN₃) and combinations thereof. One or more lumiphoric materials may be provided on one or more portions of an LED chip and/or a submount in various configurations.

Light emitted by the active layer or region of an LED chip may typically travel in a variety of directions. For targeted directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive”material may be configured to transmit at least 50% of emitted radiation of a desired wavelength.

The present disclosure may be useful for LED chips having a variety of geometries, including flip-chip geometries. Flip-chip structures for LED chips typically include anode and cathode connections that are made from a same side or face of the LED chip. The anode and cathode side is typically structured as a mounting face of the LED chip for flip-chip mounting to another surface, such as a printed circuit board. In this regard, the anode and cathode connections on the mounting face serve to mechanically bond and electrically couple the LED chip to the other surface. When flip-chip mounted, the opposing side or face of the LED chip corresponds with a light-emitting face that is oriented toward an intended emission direction. In certain embodiments, a growth substrate for the LED chip may form and/or be adjacent to the light-emitting face when flip-chip mounted. During chip fabrication, the active LED structure may be epitaxially grown on the growth substrate.

Growth substrates may typically include many materials, such as sapphire (Al₂O₃), SiC, aluminum nitride (AlN), and GaN. Sapphire is a common substrate for Group III nitrides and has certain advantages, including being lower cost, having established manufacturing processes, and having good light transmissive optical properties. However, sapphire is also known to exhibit guided modes for light propagation that result in some lateral waveguiding within the substrate. In this manner, light emission patterns for sapphire-based flip-chips may not be entirely Lambertian in nature. Rather, increased intensities of light may exit toward perimeter edges of such LED chips.

Aspects of the present disclosure are provided that include optical arrangements for cover structures of LED packages for improving or otherwise tailoring emission characteristics. Such cover structures may include hard and mechanically robust structures that are positioned over one or more LED chips within an LED package. A cover structure may be configured to provide protection from environmental exposure to underlying portions of an LED package, thereby providing a more robust LED package that is well suited for applications that require high power with increased light intensity, contrast, and reliability, such as interior and exterior automotive applications. Cover structures may comprise host materials such as glass or ceramics that provide mechanically robust structures for environmental protection. Such cover structures may be fabricated by providing sheets of glass frit or ceramic precursor materials, pressing the sheets into planar shapes, and firing or sintering to form hardened structures that can be cut or separated. The resulting cover structure may be referred to as a glass plate or a ceramic plate. When lumiphoric materials, such as phosphors, are included in the glass frit or ceramic precursor materials, the resulting cover structures may be referred to as phosphor in glass (PiG) plates or ceramic phosphor plates. In an embodiment, a transparent ceramic cover structure could be sprayed with a phosphor and silicone mixture to generate a remote phosphor with improved emission characteristics. Conventional phosphor can tend to exhibit non-uniformity of emissions due to poor color over angle for light that is converted. It is to be appreciated herein that when a 3D shaped PiG cover structure or PiG cover structure is referred to, that in different embodiments, the cover structure could be a transparent ceramic cover structure.

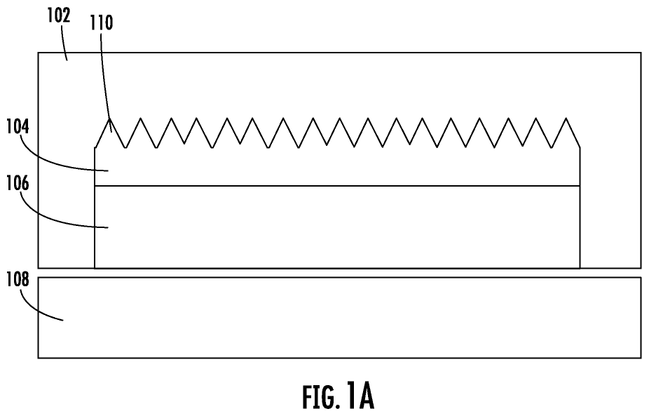

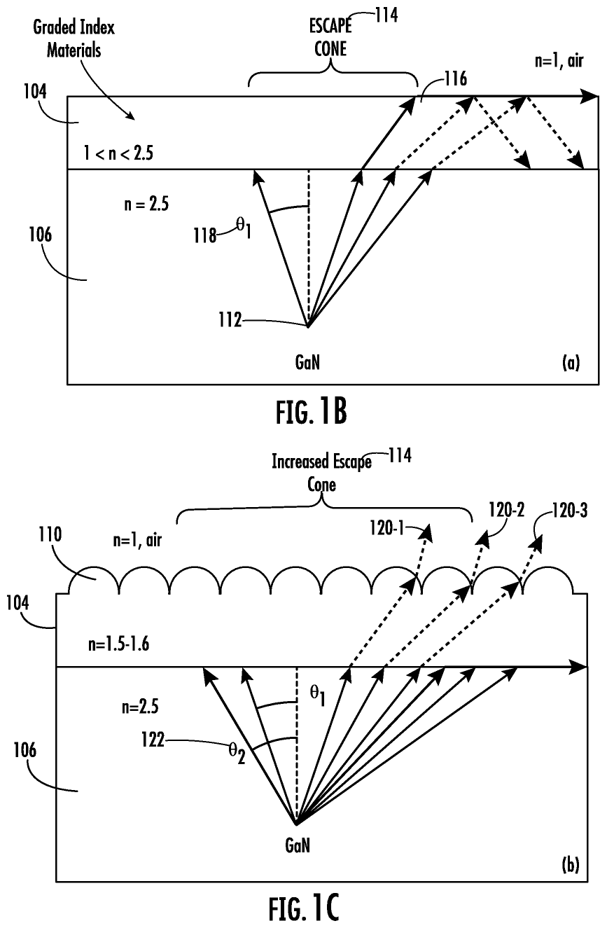

FIG. 1A is an exemplary generalized LED package with light-extraction features 110 on a cover structure 104 over an LED chip 106. The LED chip 106 can be mounted on a substrate 108. In some embodiments, the LED package can include a dome 102 over the cover structure as well. The dome 102, although depicted as rectangular in this image, could be hemispherical shaped. The light extraction features 110 can improve the ability of light to escape the cover structure 104 either into the air or into another medium.

This is depicted in more detail in FIG. 1B where light that originates from an arbitrary point 112 may be defined by an escape cone 114 where light incident at a top surface of cover structure 104 will escape and light outside the escape cone 114 will not be able to escape the cover structure 104. An exemplary light path for incident light outside the escape cone 114 is illustrated by light ray 116. The angle θ₁ 118 of the escape cone 114 can be based on the index of refraction of the cover structure 104 and the air or whatever medium the light is passing into.

As depicted in FIG. 1C, when light extraction features 110 are included in the cover structure 104, the escape cone 114 is increased in size to angle θ₂ 122, and light rays 120-1, 120-2, and 120-3 can exit the cover structure 104 even though they were outside of the original escape cone 114 since the angle at which they are incident on the surface of the light extraction feature is such that the light rays are not internally reflected.

The cover structure 104 can be a lumiphoric layer to increase light extraction efficiency and reduce color over angle shifts. The cover structure 104 can be a phosphor in glass (PiG) layer, where the phosphor is the lumiphoric element. The cover structure 104 could also be phosphor in silicone, ceramic, or a single crystal lumiphore element.

The light extraction features 110 can be periodic or arrayed in a pattern on a surface of the cover structure 104. The light extraction features could also be randomly sized and/or arranged. In various embodiments, the height or thickness of the light extraction features can be between 10 nm and 100 μm. The periodicity, or distance between the features can also be between 10 nm and 100 μm. In various embodiments, a light extraction feature of a large size can include one or more smaller light extraction features formed on the larger light extraction feature. In another embodiment, an average ratio of a height to a width of light extraction features of the plurality of light extraction features is in a range from 0.3 to 1.

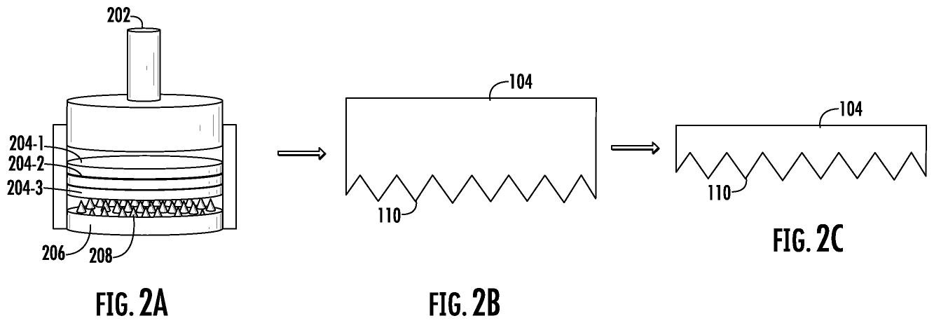

FIGS. 2A, 2B, and 2C illustrate exemplary steps in a process to manufacture an LED package with light-extraction features according to one or more embodiments of the disclosure.

FIG. 2A illustrates a cross-sectional view at a first fabrication step where multiple sheets 204-1, 204-2, and 204-3 of precursor materials are provided that could have the same optical arrangements as each other, and in other embodiments have different optical arrangements from one another. In certain embodiments, a precursor material for a glass plate may comprise glass frit and a corresponding binder, and a precursor material for a ceramic plate may comprise ceramic materials and a corresponding binder. The precursor materials may typically be formed as a slurry that is dried to form the corresponding sheets 204-1, 204-2, and 204-3. As described herein, the sheets 204-1, 204-2, and 204-3 may sometimes be referred to as green sheets that refer to composite sheets before firing. By way of example, each of the sheets 204-1, 204-2, and 204-3 may comprise an optical material, such as a lumiphoric material (e.g., phosphor). In still further embodiments, the lumiphoric materials may be provided with uniform or graded loading amounts or quantities within the precursor material, such as progressively decreasing quantities of lumiphoric material from the first sheet 204-1 toward the last sheet 204-3. Depending on the desired emission characteristics, the loading amounts of lumiphoric materials may be provided in other arrangements, including progressively increasing amounts from the first sheet 204-1 toward the last sheet 204-3, or distributions increasing and decreasing from the first sheet 204-1 toward the last sheet 204-3. While FIG. 2A is described in the context of lumiphoric materials, the sheets 204-1, 204-2, and 204-3 may include one or more combinations with other optical arrangements of optical materials, including arrangements of materials with different indexes of refraction, light-scattering materials, and light-diffusing materials separately or in combination with lumiphoric materials. Additionally, while FIG. 2A is illustrated with three sheets 204-1, 204-2, and 204-3, the concepts disclosed may be applicable to any number of sheets. In certain embodiments, the number of sheets 204-1, 204-2, and 204-3 comprises a range from 2 to 10 sheets, or a range from 2 to 8 sheets, or a range from 2 to 6 sheets. Thickness ranges for the sheets 204-1, 204-2, and 204-3 may be tailored to particular applications, with some ranges being provided in a range from 20 microns (μm) to 500 μm, or in a range from 20 μm to 300 μm, or in a range from 50 μm to 250 μm, or in a range from 100 μm to 200 μm.

FIG. 2A further illustrates where the multiple sheets 204-1, 204-2, and 204-3 are pressed together by a press 202 and mold 206 and fired to form a cover structure 104 as depicted in FIG. 2B. The mold 206 can include textured surface 208 such that when the green sheets 204-1, 204-2, and 204-3 are pressed by the press 202 into the mold 206, the textured surface 208 can leave an imprint that forms the light extraction features 110 seen in FIG. 2B. While the press 202 is pressing the green sheets 204-1, 204-2, and 204-3 into the mold 206 the green sheets 204-1, 204-2, and 204-3 can be baked and/or sintered at 500° C. or above at a pressure of greater than 500 PSI to form the cover structure 104. During firing, binder materials of the sheets 204-1, 204-2, and 204-3 are reduced and/or removed, thereby providing the cover structure 104 as a rigid structure with the various sublayers 204-1, 204-2, and 204-3 having different optical characteristics. As binder materials are removed during firing, the cover structure 104 may comprise a compressed thickness relative to a sum of the respective sheets 204-1, 204-2, and 204-3 before pressing and firing. By way of example, if each of the three sheets 204-1, 204-2, and 204-3 was provided with an initial thickness of 200 μm for a total of 600 μm when stacked, the resulting cover structure 104 may have a final thickness in a range from 400 μm to 1 mm after firing. After firing, the cover structure 104 may optionally be subjected to a removal process, such as polishing, the result of which is shown in FIG. 2C, where the thickness of the cover structure 104 is further reduced to a targeted range. In certain embodiments, thicknesses of cover structure 104 intended for LED package applications, may have a final thickness in a range from 25 μm to 500 μm, or in a range from 25 μm to 300 μm, or in a range from 100 μm to 250 μm.

In an embodiment, as the cover structure 104 cools after being pressed and baked/sintered, there would be some shrinkage of the light extraction features 110 due to contraction.

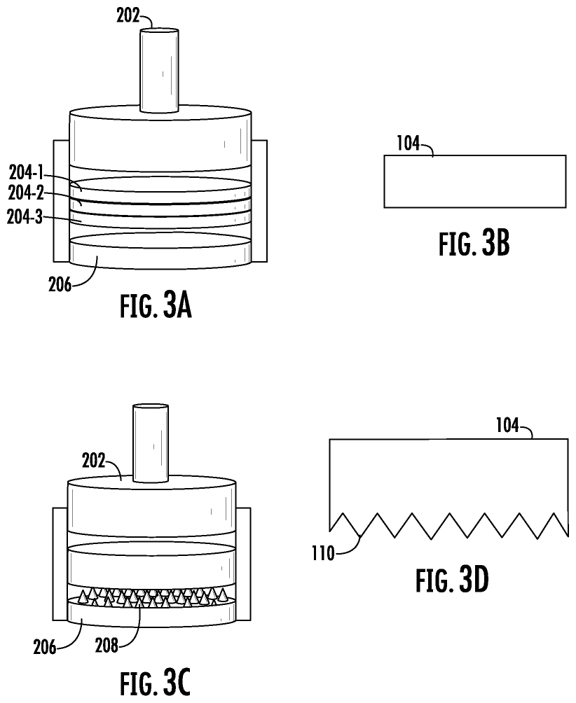

In an alternative embodiment, as shown in FIGS. 3A-3D, the green sheets 204-1, 204-2, and 204-3 can be pressed and baked and/or sintered (see FIG. 3A) by a press 202 and mold 206 that does not have the textured surface 208. After baking and sintering, the resulting cover structure 104 does not have the light extraction features as shown in FIG. 3B, but then subsequently, as shown in FIG. 3C, the cover structure can be pressed by a press 202 and mold 206 that includes the textured surface 208. During this press, the cover structure 104 would be heated to a temperature above the transition temperature of the cover structure 104 but below the decomposition point of the phosphor or other lumiphoric particles within the cover structure 104. This heating would be done slowly to avoid thermal shock of the cover structure 104. Once the cover structure 104 is at the correct temperature, the imprinting press 202 (fitting into the press die) would be used to create the imprint. This plunger would need to be at the same temperature as the die/PiG assembly to avoid shock. The imprinting would need to be done very slowly with higher temperatures allowing for quicker processing. After the imprinting is completed, the press 202, mold 206, and cover structure 104 would be cooled slowly. During the cooling process there would be slight shrinkage of the features due to contraction but not nearly to the extent of the cover structure 104 contraction upon bake out and annealing as shown in FIGS. 2A-2C.

The polishing process to thin the cover structure 104 to the desired thickness can occurring either before the light extraction features 110 are formed in FIG. 3C, or after the light extraction features 110 are formed (e.g., in FIG. 3D).

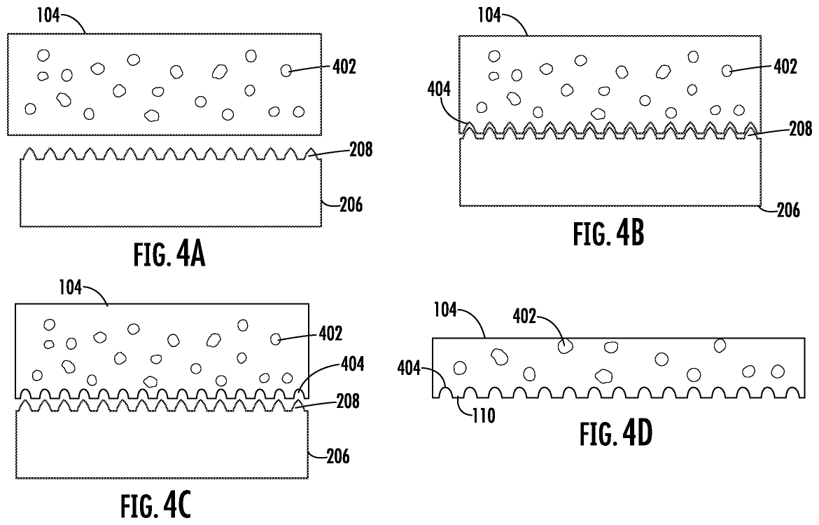

FIGS. 4A-4D illustrate exemplary steps in method of baking or heating a cover structure after light-extraction features are formed according to one or more embodiments of the disclosure. FIG. 4A provides a cross-sectional diagram of the cover structure 104 being pressed to form light extraction features 110 (e.g., as shown in FIG. 3C). The cover structure 104 can include lumiphoric particles 402 such as phosphor, and the sharp trenches 404 formed by the textured surface 208 as shown in FIG. 4B, can smooth and soften as shown in FIG. 4C once the pressure decreases and the cover structure 104 begins to cool down. After the cover structure 104 is cooled, the cover structure 104 can be ground and polished resulting, in a reduced thickness cover structure 104 in FIG. 4D that is ready to be fixed and/or mounted to a top of an LED chip.

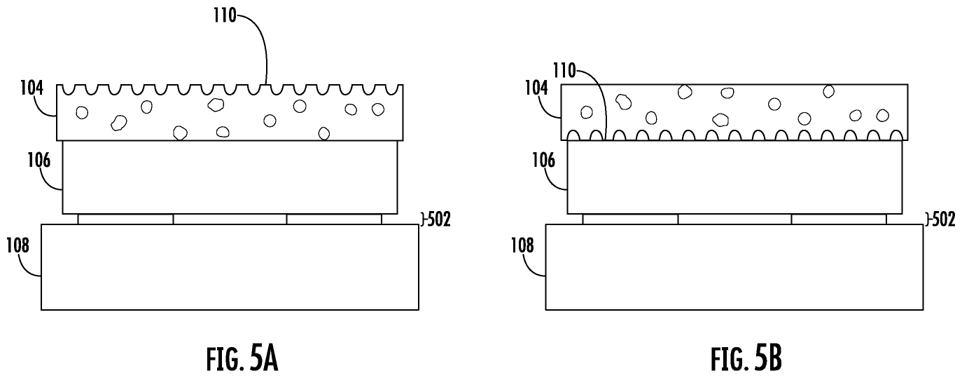

FIGS. 5A and 5B illustrate different orientations of a cover structure with light-extraction features according to one or more embodiments of the disclosure. The cover structure 104 can be placed where the light extraction features 110 are either facing away and or towards an outside surface as shown in FIG. 5A. Alternatively, the cover structure 104 can fixed to the top surface of the LED chip 106 such that the light extraction features 110 are facing the top surface of the LED chip 106 as shown in FIG. 5B. FIGS. 5A and 5B also depict the cathode and anode 502 interconnects between the substrate 108 and LED chip 106.

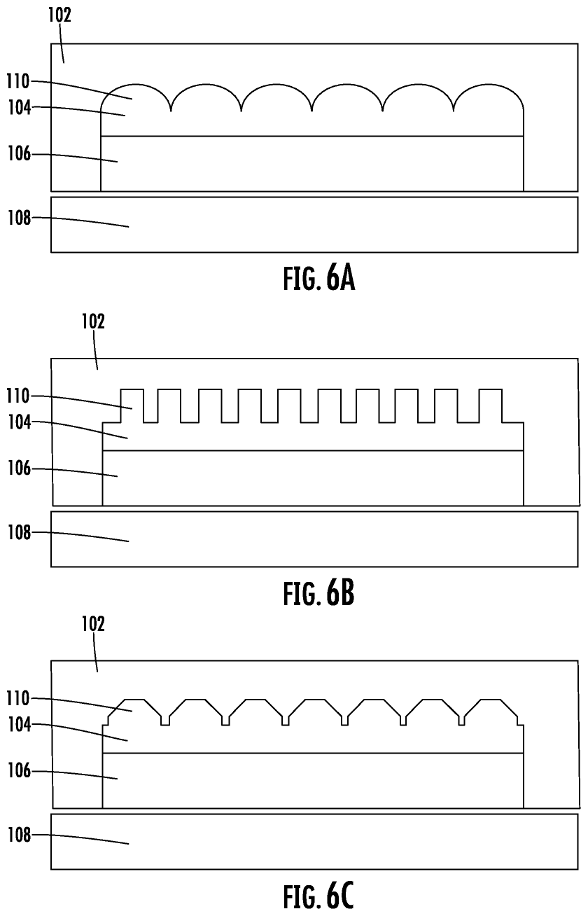

FIGS. 6A-6C illustrate various LED packages with different shapes of light-extraction features for tailoring emission characteristics according to one or more embodiments of the disclosure. The light extraction features 110 can be soft rounded ships as shown in FIG. 6A or cylindrical or rectangular shapes as shown in FIG. 6B, or other shapes such as trapezoidal as shown in FIG. 6C. In yet other embodiments, the light extraction features 110 could be irregular or randomly shaped provided that an average ratio of a height to a width of light extraction features 110 is in a range from 0.3 to 1. Each of the shapes of the light extraction features 110 depicted in FIGS. 6A-6C may be implemented alone or in combination with each other in a same cover structure 104 depending on desired emission characteristics.

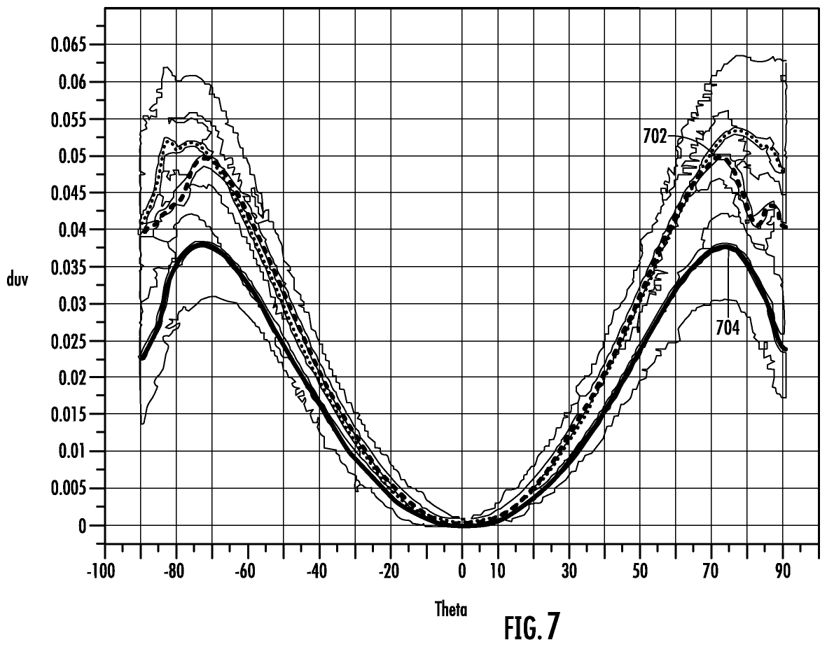

FIG. 7 is a graph depicting a change in emission profile over angle according to one or more embodiments of the disclosure. The y-axis is change in emission profile while the x-axis is the angle away from a normal angle relative to a surface of the LED chip 106. The graph depicts the change in emission profile over angle of a traditional cover structure 702, relative to the cover structure 104 disclosed here in at 704, which clearly shows a reduction in the change in emission profile at higher angles relative to the traditional cover structure 702.

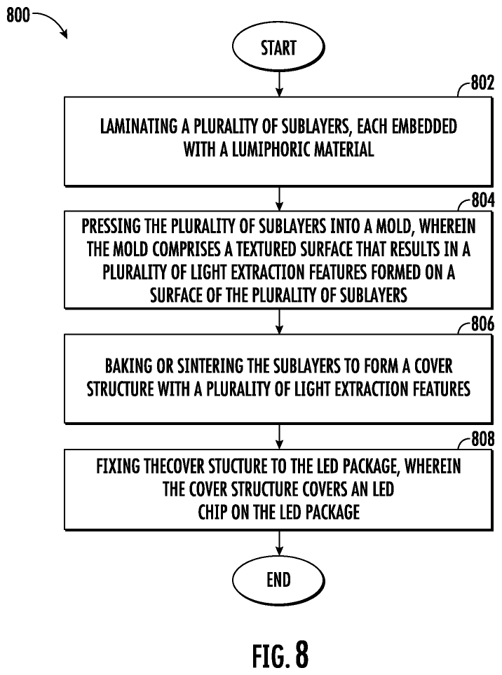

FIG. 8 is a flowchart depicting a method for fabricating an LED package according to one or more embodiments of the disclosure.

Method 800 can begin at step 802 where the method includes laminating a plurality of sublayers, each embedded with a lumiphoric material. In an embodiment, the lumiphoric material is phosphor.

At 804, the method includes pressing the plurality of sublayers into a mold, wherein the mold comprises a textured surface that results in a plurality of light extraction features formed on a surface of the plurality of sublayers. In an embodiment, a feature size of a light extraction feature of the plurality of light extraction features is between 10 nm and 100 μm and a distance between each light extraction feature of the plurality of light extraction features is between 10 nm and 100 μm. In another embodiment, an average ratio of a height to a width of the light extraction features of the plurality of light extraction features is in a range from 0.3 to 1.

At 806, the method includes baking or sintering the sublayers to form a cover structure with a textured surface. In an embodiment, the cover structure is one of a phosphor in glass cover structure, a silicone cover structure, a ceramic cover structure, or a single crystal cover structure.

At 808, the method includes fixing the cover structure to the LED package, wherein the cover structure covers an LED chip on the LED package. In an embodiment, the textured surface of the cover structure is fixed to the LED chip, whereas in other embodiments, a surface of the cover structure opposite the textured surface is fixed to the LED chip.

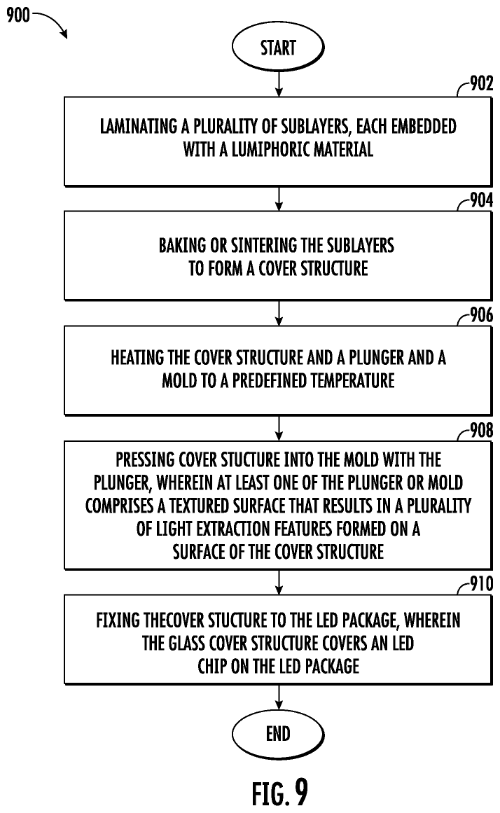

FIG. 9 is a flowchart depicting a method for fabricating an LED package according to one or more embodiments of the disclosure.

Method 900 can begin at step 902 where the method includes laminating a plurality of sublayers, each embedded with a lumiphoric material. In an embodiment, the lumiphoric material is phosphor.

At 904, the method includes baking or sintering the sublayers to form a cover structure. In an embodiment, the cover structure is one of a phosphor in glass cover structure, a silicone cover structure, a ceramic cover structure, or a single crystal cover structure.

At 906, the method includes heating the cover structure and a plunger and a mold to a predefined temperature. In an embodiment, the predefined temperature is above a transition temperature of the cover structure and below a decomposition temperature of the lumiphoric material.

At 908, the method includes pressing cover structure into the mold with the plunger, wherein at least one of the plunger or mold comprises a textured surface that results in a plurality of light extraction features formed on a surface of the cover structure. In an embodiment, a feature size of a light extraction feature of the plurality of light extraction features is between 10 nm and 100 μm and a distance between each light extraction feature of the plurality of light extraction features is between 10 nm and 100 μm. In another embodiment, an average ratio of a height to a width of the light extraction features of the plurality of light extraction features is in a range from 0.3 to 1.

At 910, the method includes fixing the cover structure to the LED package, wherein the glass cover structure covers an LED chip on the LED package.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method for fabricating a light emitting diode (LED) package, comprising:
laminating a plurality of sublayers, each embedded with a lumiphoric material;
pressing the plurality of sublayers into a mold, wherein the mold comprises a textured surface that results in a plurality of light extraction features formed on a surface of the plurality of sublayers;
baking or sintering the sublayers to form a cover structure with the plurality of light extraction features; and
fixing the cover structure to the LED package, wherein the cover structure covers an LED chip on the LED package.

2. The method of claim 1, wherein a feature size of a light extraction feature of the plurality of light extraction features is between 10 nm and 100 μm.

3. The method of claim 1, wherein a distance between each light extraction feature of the plurality of light extraction features is between 10 nm and 100 μm.

4. The method of claim 1, wherein an average ratio of a height to a width of light extraction features of the plurality of light extraction features is in a range from 0.3 to 1.

5. The method of claim 1, further comprising:
prior to fixing the cover structure to the LED package, grinding and polishing the cover structure to a predefined thickness, wherein a first surface of the cover structure opposite a second surface that comprises the plurality of light extraction features is ground and polished.

6. The method of claim 1, wherein the baking or sintering the sublayers to form the cover structure results in feature smoothing of plurality of light extraction features.

7. The method of claim 1, wherein the cover structure is one of a phosphor in glass cover structure, a silicone cover structure, a ceramic cover structure, or a single crystal cover structure.

8. The method of claim 1, wherein a first group of light-extraction features of the plurality of light extraction features comprises at least one of a different height or width than a second group of light extraction features of the plurality of light extraction features.

9. The method of claim 1, wherein a surface with the plurality of light-extraction features of the cover structure is fixed to the LED chip.

10. The method of claim 1, wherein a surface of the cover structure opposite the surface with the plurality of light-extraction features is fixed to the LED chip.

11. A method for fabricating a light emitting diode (LED) package, comprising:
laminating a plurality of sublayers, each embedded with a lumiphoric material;
baking or sintering the sublayers to form a cover structure;
heating the cover structure and a plunger and a mold to a predefined temperature;
pressing the cover structure into the mold with the plunger, wherein at least one of the plunger or mold comprises a textured surface that results in a plurality of light extraction features formed on a surface of the cover structure; and
fixing the cover structure to the LED package, wherein the cover structure covers an LED chip on the LED package.

12. The method of claim 11, further comprising:
grinding and polishing the cover structure to a predefined thickness, wherein a first surface of the cover structure opposite a second surface that comprises the plurality of light extraction features is ground and polished.

13. The method of claim 11, wherein the predefined temperature is above a transition temperature of the cover structure and below a decomposition temperature of the lumiphoric material.

14. The method of claim 11, wherein the lumiphoric material is phosphor.

15. The method of claim 11, wherein the cover structure is one of a phosphor in glass cover structure, a silicone cover structure, a ceramic cover structure, or a single crystal cover structure.

16. The method of claim 11, wherein a feature size of a light extraction feature of the plurality of light extraction features is between 10 nm and 100 μm.

17. The method of claim 11, wherein a distance between each light extraction feature of the plurality of light extraction features is between 10 nm and 100 μm.

18. The method of claim 11, wherein an average ratio of a height to a width of the light extraction features of the plurality of light extraction features is in a range from 0.3 to 1.

19. The method of claim 11, wherein a first group of light-extraction features of the plurality of light extraction features comprises at least one of a different height or width than a second group of light extraction features of the plurality of light extraction features.

20. The method of claim 11, wherein the surface with the plurality of light-extraction features of the cover structure is fixed to the LED chip.

21. The method of claim 11, wherein a surface of the cover structure opposite the surface with the plurality of light-extraction features is fixed to the LED chip.
